(19) United States
(12) Patent Application Publication
(10) Pub. No.: US 2026/0326310 A1
(43) Pub. Date: Oct. 22, 2026

(54) SUBSTRATE TRANSPORT ROBOT SYSTEM, AND METHOD FOR CORRECTING POSITION OF SUBSTRATE PLACEMENT AND/OR POSITION OF SUBSTRATE PICK-UP BY SUBSTRATE TRANSPORT ROBOT

(71) Applicant: KAWASAKI JUKOGYO KABUSHIKI KAISHA, Kobe-shi, Hyogo (JP)

(72) Inventors: Takeshi SHIBATA, Kobe-shi (JP); Satoshi HASHIZAKI, Kobe-shi (JP)

(73) Assignee: KAWASAKI JUKOGYO KABUSHIKI KAISHA, Kobe-shi, Hyogo (JP)

(21) Appl. No.: 19/117,532

(22) PCT Filed: Oct. 6, 2023
(86) PCT No.: PCT/JP2023/036553

§ 371 Date: Apr. 1, 2025

(30) Foreign Application Priority Data
Oct. 7, 2022 (JP) 2022-162694

(51) Int. Cl. B25J 13/08; B25J 15/00

(52) U.S. Cl. CPC B25J 13/088; B25J 15/0014

(57) ABSTRACT

A substrate transport robot system includes a controller configured or programmed to acquire a center position of a target member in a horizontal plane based on a first tangent corresponding to an outer periphery of the target member acquired using a detector while a hand is caused to approach the target member from a first direction in the horizontal plane, and a second tangent corresponding to the outer periphery of the target member acquired using the detector while the hand is caused to approach the target member from a second direction in the horizontal plane different from the first direction.

### TECHNICAL FIELD

The present disclosure relates to a substrate transport robot system, and a method for correcting a position of substrate placement and/or a position of substrate pick-up by a substrate transport robot.

### BACKGROUND ART

Conventionally, a substrate transport robot that corrects a position of substrate placement in a horizontal plane is known. For example, Japanese Patent No. 6637494 discloses a substrate transport robot that corrects a position of substrate placement in a horizontal plane based on the identified center position of a target in the horizontal plane and the previously acquired relative positional relationship in the horizontal plane between the center position of the target and a placement area of the substrate. The target is disposed at a predetermined position with respect to the placement area of the substrate in order to correct the position of substrate placement in the horizontal plane.

The substrate transport robot disclosed in Japanese Patent No. 6637494 identifies the center position of the target in the horizontal plane, as described below. First, a hand attached to a distal end of a robot arm is brought closer to the target until the target begins to be detected by a sensor. Then, the hand is swung. An offset amount of the hand is calculated based on a change in a detection signal of the sensor caused by swinging the hand. The position of the hand is shifted based on the calculated offset amount. Then, swinging of the hand, calculation of the offset amount of the hand, shifting of the position of the hand, etc. are repeated until the center position of the target in the horizontal plane is identified.

### PRIOR ART

### Patent Document

Patent Document 1: Japanese Patent No. 6637494

### SUMMARY OF THE INVENTION

However, in the substrate transport robot described in Japanese Patent No. 6637494, in order to identify the center position of the target in the horizontal plane, it is necessary to repeat swinging of the hand, calculation of the offset amount of the hand, shifting of the position of the hand, etc., and thus the time required to identify the position of the target in the horizontal plane is conceivably relatively long. In other words, the time required to correct the position of substrate placement in the horizontal plane is conceivably relatively long.

Although not described in the above Patent Document 1, in a substrate transport robot such as that described in Japanese Patent No. 6637494, when a position of substrate pick-up in a horizontal plane is corrected, the same problem as that when a position of substrate placement in the horizontal plane is corrected is conceivable.

Therefore, a configuration capable of shortening the time required to correct the position of substrate placement and/or the position of substrate pick-up in the horizontal plane is desired.

The present disclosure is intended to solve the above problem. The present disclosure aims to provide a substrate transport robot system, and a method for correcting a position of substrate placement and/or a position of substrate pick-up by a substrate transport robot each capable of shortening the time required to correct the position of substrate placement and/or the position of substrate pick-up in a horizontal plane.

In order to attain the aforementioned object, a substrate transport robot system according to a first aspect of the present disclosure includes a substrate transport robot to transport a substrate, a horizontal target member having a circular shape as viewed in an upward-downward direction and used to correct a position of substrate placement and/or a position of substrate pick-up in a horizontal plane, and a controller. The substrate transport robot includes a robot arm, a hand attached to a distal end of the robot arm, and a detector on the hand to detect an outer periphery of the horizontal target member. The controller is configured or programmed to acquire a center position of the horizontal target member in the horizontal plane based on a first tangent corresponding to the outer periphery of the horizontal target member acquired using the detector while the hand is caused to approach the horizontal target member from a first direction in the horizontal plane, and a second tangent corresponding to the outer periphery of the horizontal target member acquired using the detector while the hand is caused to approach the horizontal target member from a second direction in the horizontal plane different from the first direction, and correct the position of substrate placement and/or the position of substrate pick-up in the horizontal plane based on an acquired center position of the horizontal target member in the horizontal plane and a previously acquired relative positional relationship in the horizontal plane between the center position of the horizontal target member and a placement area of the substrate.

In the substrate transport robot system according to the first aspect of the present disclosure, as described above, the controller is configured or programmed to acquire the center position of the horizontal target member in the horizontal plane based on the first tangent corresponding to the outer periphery of the horizontal target member acquired using the detector while the hand is caused to approach the horizontal target member from the first direction in the horizontal plane, and the second tangent corresponding to the outer periphery of the horizontal target member acquired using the detector while the hand is caused to approach the horizontal target member from the second direction in the horizontal plane different from the first direction. Accordingly, when the first tangent and the second tangent are each acquired once, the center position of the horizontal target member can be acquired immediately based on the first tangent and the second tangent. In other words, the center position of the horizontal target member in the horizontal plane can be quickly acquired as compared with a case in which swinging of the hand, calculation of the offset amount of the hand, shifting of the position of the hand, etc. are repeated in order to identify the center position of the target member in the horizontal plane. Accordingly, the position of substrate placement and/or the position of substrate pick-up in the horizontal plane can be quickly corrected. Consequently, the time required to correct the position of substrate placement and/or the position of substrate pick-up in the horizontal plane can be shortened.

In order to attain the aforementioned object, a method for correcting a position of substrate placement and/or a position of substrate pick-up by a substrate transport robot according to a second aspect of the present disclosure is a method for correcting a position of substrate placement and/or a position of substrate pick-up by a substrate transport robot including a robot arm, a hand attached to a distal end of the robot arm, and a detector to detect a horizontal target member having a circular shape as viewed in an upward-downward direction, the horizontal target member being used to correct a position of substrate placement and/or a position of substrate pick-up in a horizontal plane, the substrate transport robot being operable to transport a substrate, and includes acquiring a first tangent corresponding to an outer periphery of the horizontal target member using the detector while the hand is caused to approach the horizontal target member from a first direction in the horizontal plane, acquiring a second tangent corresponding to the outer periphery of the horizontal target member using the detector while the hand is caused to approach the horizontal target member from a second direction in the horizontal plane different from the first direction, acquiring a center position of the horizontal target member based on an acquired first tangent and an acquired second tangent, and correcting the position of substrate placement and/or the position of substrate pick-up in the horizontal plane based on an acquired center position of the horizontal target member and a previously acquired relative positional relationship in the horizontal plane between the center position and a placement area of the substrate.

In the method for correcting the position of substrate placement and/or the position of substrate pick-up by the substrate transport robot according to the second aspect of the present disclosure, as described above, the first tangent to the outer periphery of the horizontal target member is acquired using the detector while the hand is caused to approach the horizontal target member from the first direction in the horizontal plane.

Furthermore, the second tangent to the outer periphery of the horizontal target member is acquired using the detector while the hand is caused to approach the horizontal target member from the second direction in the horizontal plane different from the first direction. The center position of the horizontal target member is acquired based on the acquired first tangent and the acquired second tangent. Accordingly, similarly to the substrate transport robot system according to the first aspect, when the first tangent and the second tangent are acquired once, the center position of the horizontal target member can be acquired immediately based on the first tangent and the second tangent. Consequently, similarly to the substrate transport robot system according to the first aspect, the time required to correct the position of substrate placement and/or the portion of substrate pick-up in the horizontal plane can be shortened.

According to the present disclosure, as described above, it is possible to provide the substrate transport robot system, and the method for correcting the position of substrate placement and/or the position of substrate pick-up by the substrate transport robot each capable of shortening the time required to correct the position of substrate placement and/or the position of substrate pick-up in the horizontal plane.

### BRIEF DESCRIPTION OF THE DRAWINGS

FIG. 1 is a plan view showing the overall configuration of a substrate transport robot system according to an embodiment of the present disclosure.

FIG. 2 is a perspective view showing a substrate transport robot according to the embodiment of the present disclosure.

FIG. 3 is a diagram for illustrating acquisition of a first tangent in the substrate transport robot system according to the embodiment of the present disclosure.

FIG. 4 is a diagram for illustrating acquisition of a second tangent in the substrate transport robot system according to the embodiment of the present disclosure.

FIG. 5 is a diagram for illustrating acquisition of the center position of a target member in the substrate transport robot system according to the embodiment of the present disclosure.

FIG. 6 is a diagram for illustrating acquisition of the position of the target member in an upward-downward direction in the substrate transport robot system according to the embodiment of the present disclosure.

FIG. 7 is a diagram for illustrating acquisition of the inclination of a coordinate system of a placement area of the substrate with respect to a coordinate system of a robot arm in the substrate transport robot system according to the embodiment of the present disclosure.

FIG. 8 is a diagram showing a state in which a direction in which a hand approaches the target member is not perpendicular to the direction of detection light in the substrate transport robot system according to the embodiment of the present disclosure.

FIG. 9 is a diagram for illustrating acquisition of the inclination of a direction perpendicular to the direction of the detection light with respect to the direction in which the hand approaches the target member in the substrate transport robot system according to the embodiment of the present disclosure.

FIG. 10 is a diagram showing a state in which the direction in which the hand approaches the target member is perpendicular to the direction of the detection light in the substrate transport robot system according to the embodiment of the present disclosure.

FIG. 11 is a substrate placement position correction flowchart in the substrate transport robot system according to the embodiment of the present disclosure.

### MODES FOR CARRYING OUT THE INVENTION

An embodiment embodying the present disclosure is hereinafter described on the basis of the drawings.

### Configuration of Substrate Transport Robot System

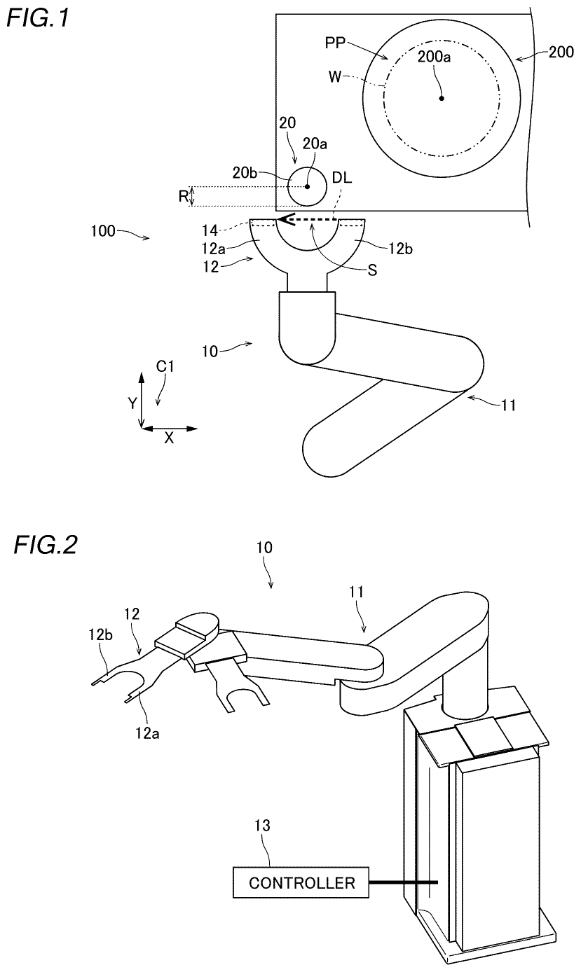

The configuration of a substrate transport robot system 100 according to the embodiment of the present disclosure is now described with reference to FIGS. 1 to 10.

### Overall Configuration of Substrate Transport Robot System

As shown in FIG. 1, the substrate transport robot system 100 includes a substrate transport robot 10 and a target member 20. The target member 20 is an example of a horizontal target member, a first horizontal target member, or an up-down target member.

The substrate transport robot 10 is a robot that transports a substrate W to a placement area 200 of the substrate W. The placement area 200 of the substrate W is a front opening unify pod (FOUP), for example.

The target member 20 is a member for correcting a position PP of substrate W placement in a horizontal plane and in an upward-downward direction by the substrate transport robot 10. That is, the target member 20 is a member for performing correction to cause the position PP of substrate W placement to coincide with the placement area 200 of the substrate W. The target member 20 is placed at a predetermined position set in advance with respect to the placement area 200 of the substrate W.

That is, the relative positional relationship in the horizontal plane between the center position 20a of the target member 20 and the placement area 200 of the substrate W does not change. The target member 20 has a circular shape as viewed in the upward-downward direction.

### Configuration of Substrate Transport Robot

As shown in FIG. 2, the substrate transport robot 10 includes a robot arm 11, a hand 12, and a controller 13.

The robot arm 11 is a horizontal articulated robot arm. The robot arm 11 is controlled by the controller 13 to operate a plurality of joints.

The controller 13 controls the operation of the robot arm 11, the operation of the hand 12, etc. The controller 13 includes a processor such as a central processing unit (CPU) and memories such as a read-only memory (ROM) and a random access memory (RAM).

The hand 12 is attached to a distal end of the robot arm 11. The hand 12 holds the substrate W. The hand 12 includes a distal end bifurcated into a first distal end 12a and a second distal end 12b.

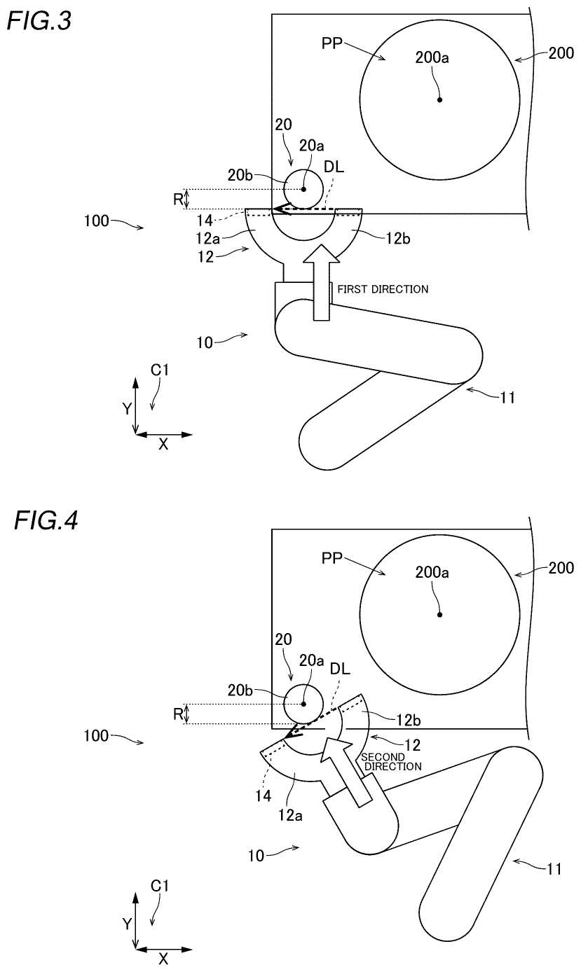

As shown in FIG. 3, the robot arm 11 includes a detector 14. The detector 14 is a mapping sensor that detects the presence or absence of the substrate W in the placement area 200 of the substrate W. The detector 14 is disposed on the hand 12. The detector 14 is a transmission sensor that detects the target member 20 based on whether or not detection light DL passing through a space S between the first distal end 12a and the second distal end 12b is blocked. Although FIG. 3 shows an example in which the detection light DL is directed from the second distal end 12b to the first distal end 12a, the detection light DL may be directed from the first distal end 12a to the second distal end 12b.

### Correction of Position of Substrate Placement in Horizontal Direction

As shown in FIG. 3, the controller 13 causes the hand 12 to approach the target member 20 from a first direction in the horizontal plane, and acquires a first tangent TL1 (see FIG. 5) corresponding to the outer periphery 20b of the target member 20 using the detector 14. Specifically, the controller 13 controls the operation of the robot arm 11 so as to cause the hand 12 to approach the target member 20 from the first direction in the horizontal plane until the outer periphery 20b of the target member 20 is detected by the detector 14. The controller 13 then acquires, as the first tangent TL1, a straight line along the direction of the detection light DL at the position of the hand 12 at which the outer periphery 20b of the target member 20 is detected by the detector 14. A direction in which the hand 12 approaches the target member 20 is parallel to a Y direction of a coordinate system C1 of the robot arm 11.

Then, as shown in FIG. 4, the controller 13 causes the hand 12 to approach the target member 20 from a second direction in the horizontal plane different from the first direction, and acquires a second tangent TL2 (see FIG. 5) corresponding to the outer periphery 20b of the target member 20 using the detector 14. Specifically, the controller 13 controls the operation of the robot arm 11 so as to cause the hand 12 to approach the target member 20 from the second direction in the horizontal plane until the outer periphery 20b of the target member 20 is detected by the detector 14. Then, the controller 13 acquires, as the second tangent TL2, a straight line along the direction of the detection light DL at the position of the hand 12 at which the outer periphery 20b of the target member 20 is detected by the detector 14.

Then, as shown in FIG. 5, the controller 13 acquires the center position 20a of the target member 20 in the horizontal plane based on the first tangent TL1 and the second tangent TL2. Specifically, the controller 13 acquires the intersection point of a perpendicular line PL1 to the first tangent TL1 and a perpendicular line PL2 to the second tangent TL2 as the center position 20a of the target member 20. In order to improve the accuracy of acquiring the center position 20a of the target member 20 in the horizontal plane, the controller 13 may use, for example, the radius R of the target member 20 in addition to the first tangent TL1 and the second tangent TL2 when acquiring the center position 20a of the target member 20 in the horizontal plane.

Then, the controller 13 corrects the position PP of substrate W placement in the horizontal plane based on the acquired center position 20a of the target member 20 in the horizontal plane and the previously acquired relative positional relationship in the horizontal plane between the center position 20a of the target member 20 and the placement area 200 of the substrate W. Specifically, the controller 13 corrects the position PP of substrate W placement in the horizontal plane based on the acquired center position 20a of the target member 20 in the horizontal plane and the previously acquired relative positional relationship in the horizontal plane between the center position 20a of the target member 20 and the center position 200a of the placement area 200 of the substrate W. The controller 13 previously acquires the relative positional relationship in the horizontal plane between the center position 20a of the target member 20 and the center position 200a of the placement area 200 of the substrate W before correcting the position PP of substrate W placement in a horizontal direction.

### Correction of Position of Substrate Placement in Upward-Downward Direction

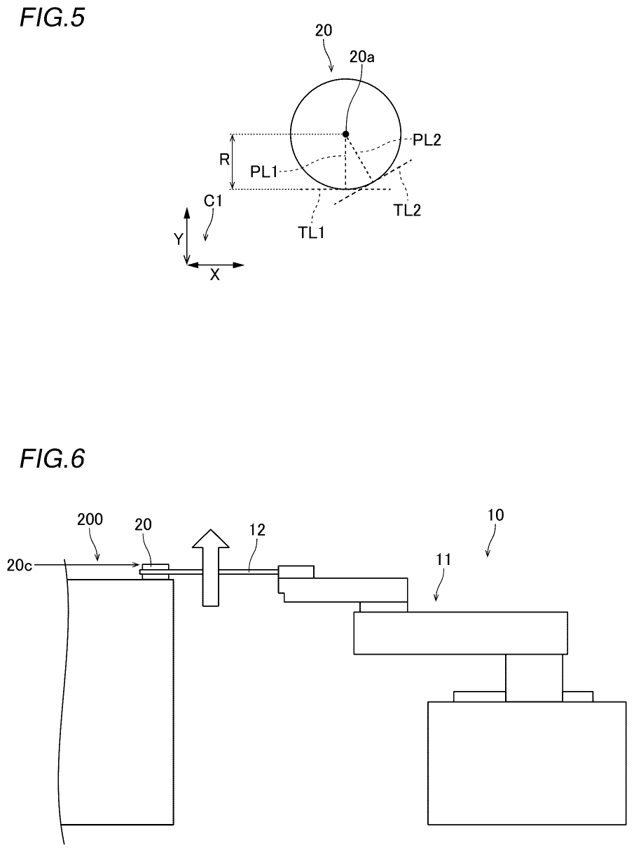

As shown in FIG. 6, the controller 13 acquires the position 20c of the target member 20 in the upward-downward direction based on the timing at which a state in which the detector 14 detects the target member 20 in the upward-downward direction and a state in which the detector 14 does not detect the target member 20 in the upward-downward direction are switched, which is acquired by moving the hand 12 in the upward-downward direction with respect to the target member 20. Specifically, the controller 13 moves the hand 12 in the upward-downward direction with respect to the target member 20 from a state in which the detector 14 detects the outer periphery 20b of the target member 20 until a state in which the detector 14 no longer detects the outer periphery 20b of the target member 20. Then, the controller 13 acquires the position 20c of the target member 20 in the upward-downward direction based on the position of the hand 12 in the upward-downward direction at the timing at which a state in which the detector 14 detects the outer periphery 20b of the target member 20 and a state in which the detector 14 does not detect the outer periphery 20b of the target member 20 are switched.

Then, the controller 13 corrects the position PP of substrate W placement in the upward-downward direction based on the acquired position 20c of the target member 20 in the upward-downward direction and the previously acquired relative positional relationship in the upward-downward direction between the position 20c of the target member 20 and the placement area 200 of the substrate W.

The controller 13 previously acquires the relative positional relationship in the upward-downward direction between the position 20c of the target member 20 and the placement area 200 of the substrate W before correcting the position PP of substrate W placement in the upward-downward direction.

### Acquisition of Inclination of Coordinate System of Placement Area of Substrate with Respect to Coordinate System of Robot Arm in Horizontal Plane

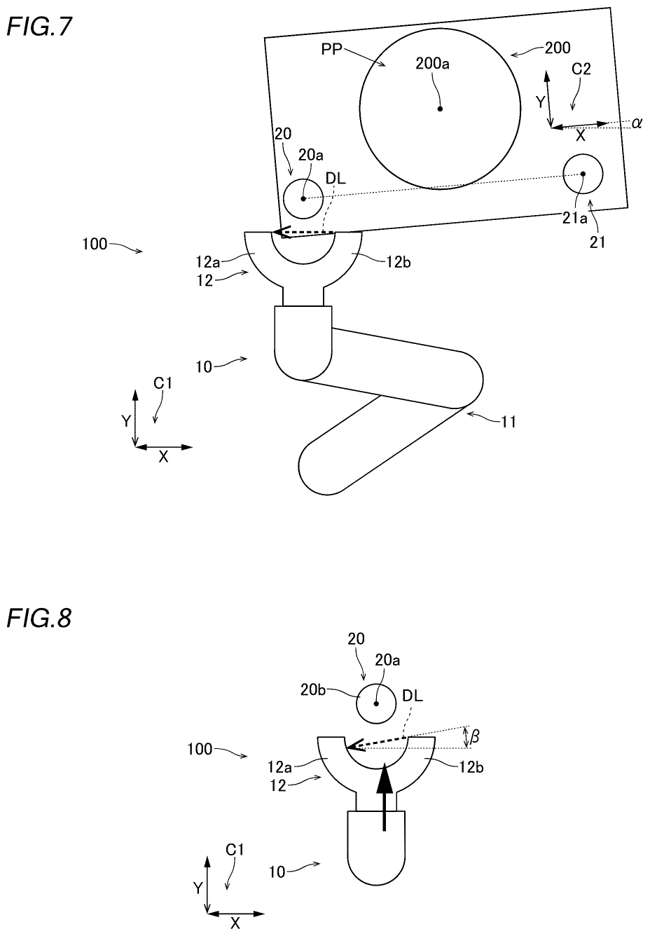

As shown in FIG. 7, a coordinate system C2 of the placement area 200 of the substrate W may be inclined with respect to the coordinate system C1 of the robot arm 11 in the horizontal plane. In such a case, the accuracy of correcting the position PP of substrate W placement in the horizontal plane decreases. Therefore, when correcting the position PP of substrate W placement in the horizontal plane, the substrate transport robot 10 preferably recognizes the inclination a of the coordinate system C2 of the placement area 200 of the substrate W with respect to the coordinate system C1 of the robot arm 11 in the horizontal plane. Therefore, before correcting the position PP of substrate W placement in the horizontal plane, the substrate transport robot 10 acquires the inclination a of the coordinate system C2 of the placement area 200 of the substrate W with respect to the coordinate system C1 of the robot arm 11 in the horizontal plane, as described below.

The substrate transport robot system 100 includes a target member 21. Similarly to the target member 20, the target member 21 is a member for correcting the position PP of substrate W placement in the horizontal plane and in the upward-downward direction by the substrate transport robot 10. The target member 21 is disposed at a position different from the position of the target member 20 in the horizontal plane. Specifically, the target member 21 is disposed on the side opposite to the target member 20.

The target member 21 is disposed such that a straight line connecting the center position 20a of the target member 20 to the center position 21a of the target member 21 is parallel to an X direction of the coordinate system C2 of the placement area 200 of the substrate W in the horizontal plane. The target member 21 is an example of a second horizontal target member or an up-down target member.

Then, the controller 13 acquires the center position 20a of the target member 20 in the horizontal plane and the center position 21a of the target member 21 in the horizontal plane by the method described above.

Then, the controller 13 acquires the inclination a of the coordinate system C2 of the placement area 200 of the substrate W with respect to the coordinate system C1 of the robot arm 11 in the horizontal plane based on the center position 20a of the target member 20 in the horizontal plane, the center position 21a of the target member 21 in the horizontal plane, and the previously acquired relative positional relationship in the horizontal plane between the center position 20a of the target member 20 and the center position 21a of the target member 21. Specifically, the controller 13 acquires the angle of the coordinate system C2 of the placement area 200 of the substrate W in the X direction with respect to an X direction of the coordinate system C1 of the robot arm 11 in the horizontal plane as the inclination a of the coordinate system C2 of the placement area 200 of the substrate W with respect to the coordinate system C1 of the robot arm 11. The controller 13 previously acquires the relative positional relationship in the horizontal plane between the center position 20a of the target member 20 and the center position 21a of the target member 21 before correcting the position PP of substrate W placement in the horizontal direction.

### Calibration of Coordinate System of Robot Arm Performed Such That Direction in Which Hand Approaches Target Member is Perpendicular to Direction of Detection Light

As shown in FIG. 8, the direction in which the hand 12 approaches the target member 20 may not be perpendicular to the direction of the detection light DL when the detector 14 is attached to the hand 12 so as to be shifted from the design position, for example. In such a case, the accuracy of correcting the position PP of substrate W placement in the horizontal plane decreases.

Therefore, when correcting the position PP of substrate W placement in the horizontal plane, the substrate transport robot 10 preferably causes the direction in which the hand 12 approaches the target member 20 to be perpendicular to the direction of the detection light DL. Therefore, before correcting the position PP of substrate W placement in the horizontal plane, the substrate transport robot 10 calibrates the coordinate system C1 of the robot arm 11, as described below, such that the direction in which the hand 12 approaches the target member 20 is perpendicular to the direction of the detection light DL.

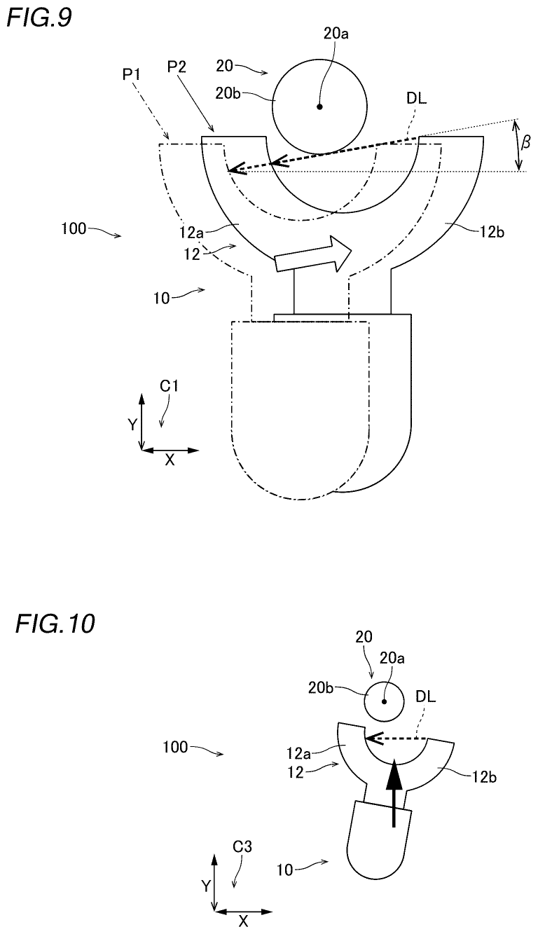

First, as shown in FIG. 9, the controller 13 causes the hand 12 to approach the target member 20 while changing the position of the hand 12 at which the detection light DL is blocked, and acquires the direction of the detection light DL with respect to the hand 12 based on a plurality of positions of the hand 12 at which the detection light DL is blocked. Specifically, the controller 13 causes the hand 12 to approach the target member 20, and acquires a first position P1 of the hand 12 at which the detection light DL is blocked. Then, the controller 13 causes the hand 12 to approach the target member 20 while moving the hand 12 in the X direction, and acquires a second position P2 of the hand 12 at which the detection light DL is blocked and that is different from the first position P1. Then, the controller 13 acquires the direction of a straight line connecting the first position P1 to the second position P2 of the hand 12 with respect to the X direction of the coordinate system C1 of the robot arm 11 as the inclination 3 of the detection light DL with respect to a direction perpendicular to the direction in which the hand 12 approaches the target member 20. In order to acquire the direction of the detection light DL with respect to the hand 12, three or more positions at which the detection light DL is blocked may be acquired.

Then, as shown in FIG. 10, the controller 13 calibrates the coordinate system C1 of the robot arm 11 based on the acquired direction of the detection light DL such that the direction in which the hand 12 approaches the target member 20 is perpendicular to the direction of the detection light DL. Specifically, the controller 13 converts the coordinate system C1 (see FIG. 8) of the robot arm 11, in which the direction in which the hand 12 approaches the target member 20 is not perpendicular to the direction of the detection light DL, into a coordinate system C3 of the robot arm 11, in which the direction in which the hand 12 approaches the target member 20 is perpendicular to the direction of the detection light DL, based on the inclination 3 of the detection light DL with respect to the direction perpendicular to the direction in which the hand 12 approaches the target member 20.

### Method for Correcting Position of Substrate Placement by Substrate Transport Robot

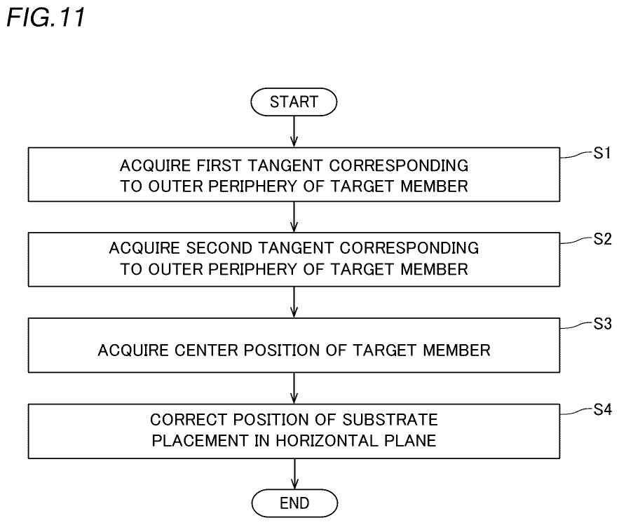

A method for correcting the position PP of substrate W placement by the substrate transport robot 10 is now described with reference to FIG. 11. In the following description of the method for correcting the position PP of substrate W placement, among the correction of the position PP of substrate W placement by the substrate transport robot 10, only the correction of the position PP of substrate W placement in the horizontal plane is described.

First, as shown in FIG. 11, in step S1, the first tangent TL1 corresponding to the outer periphery 20b of the target member 20 is acquired using the detector 14 while the hand 12 is caused to approach the target member 20 from the first direction in the horizontal plane.

Next, in step S2, the second tangent TL2 corresponding to the outer periphery 20b of the target member 20 is acquired using the detector 14 while the hand 12 is caused to approach the target member 20 from the second direction in the horizontal plane different from the first direction.

Next, in step S3, the center position 20a of the target member 20 is acquired based on the acquired first tangent TL1 and the acquired second tangent TL2.

Next, in step S4, the position PP of substrate W placement in the horizontal plane is corrected based on the acquired center position 20a of the target member 20 in the horizontal plane and the previously acquired relative positional relationship in the horizontal plane between the center position 20a of the target member 20 and the placement area 200 of the substrate W.

### Advantages of Embodiment

According to this embodiment, the following advantages are achieved.

### Advantages of Substrate Transport Robot System

According to this embodiment, the controller 13 is configured or programmed to acquire the center position 20a of the target member 20 in the horizontal plane based on the first tangent TL1 corresponding to the outer periphery 20b of the target member 20 acquired using the detector 14 while the hand 12 is caused to approach the target member 20 from the first direction in the horizontal plane, and the second tangent TL2 corresponding to the outer periphery 20b of the target member 20 acquired using the detector 14 while the hand 12 is caused to approach the target member 20 from the second direction in the horizontal plane different from the first direction. Accordingly, when the first tangent TL1 and the second tangent TL2 are each acquired once, the center position 20a of the target member 20 can be acquired immediately based on the first tangent TL1 and the second tangent TL2. In other words, the center position 20a of the target member 20 in the horizontal plane can be quickly acquired as compared with a case in which swinging of the hand 12, calculation of the offset amount of the hand 12, shifting of the position of the hand 12, etc. are repeated in order to identify the center position 20a of the target member 20 in the horizontal plane. Accordingly, the position PP of substrate W placement in the horizontal plane can be quickly corrected. Consequently, the time required to correct the position PP of substrate W placement in the horizontal plane can be shortened.

According to this embodiment, the detector 14 is operable to detect the position 20c of the target member 20 for correcting the position PP of substrate W placement in the upward-downward direction. The controller 13 is configured or programmed to acquire the position 20c of the target member 20 in the upward-downward direction based on the timing at which a state in which the detector 14 detects the target member 20 in the upward-downward direction and a state in which the detector 14 does not detect the target member 20 in the upward-downward direction are switched, which is acquired by moving the hand 12 in the upward-downward direction with respect to the target member 20. Furthermore, the controller 13 is configured or programmed to correct the position PP of substrate W placement in the upward-downward direction based on the acquired position 20c of the target member 20 in the upward-downward direction and the previously acquired relative positional relationship in the upward-downward direction between the position 20c of the target member 20 and the placement area 200 of the substrate W.

Accordingly, in addition to correction of the position PP of substrate W placement in the horizontal plane, correction of the position PP of substrate W placement in the upward-downward direction can be performed.

According to this embodiment, the target member 20 is a member for correcting the position PP of substrate W placement in the horizontal plane and in the upward-downward direction. Accordingly, correction of the position PP of substrate W placement in the horizontal plane and correction of the position PP of substrate W placement in the upward-downward direction can be performed using the common target member 20. Thus, even when correction of the position PP of substrate W placement in the upward-downward direction is performed in addition to correction of the position PP of substrate W placement in the horizontal plane, the configuration can be simplified without adding a component for correcting the position PP of substrate W placement in the upward-downward direction.

According to this embodiment, the substrate transport robot system 100 includes the target member 21 at the position different from the position of the target member 20 in the horizontal plane in addition to the target member 20. The controller 13 is configured or programmed to acquire the inclination a of the coordinate system C2 of the placement area 200 of the substrate W with respect to the coordinate system C1 of the robot arm 11 in the horizontal plane based on the center position 20a of the target member 20 in the horizontal plane, the center position 21a of the target member 21 in the horizontal plane, and the previously acquired relative positional relationship in the horizontal plane between the center position 20a of the target member 20 and the center position 21a of the target member 21. Accordingly, even when the coordinate system C2 of the placement area 200 of the substrate W is inclined with respect to the coordinate system C1 of the robot arm 11 in the horizontal plane, the substrate transport robot 10 can recognize the inclination a of the coordinate system C2 of the placement area 200 of the substrate W with respect to the coordinate system C1 of the robot arm 11 in the horizontal plane. Accordingly, a decrease in the accuracy of correcting the position PP of substrate W placement in the horizontal plane, which is caused by the coordinate system C2 of the placement area 200 of the substrate W being inclined with respect to the coordinate system C1 of the robot arm 11 in the horizontal plane, can be reduced or prevented. Furthermore, as described above, the center position 20a of the target member 20 in the horizontal plane and the center position 21a of the target member 21 in the horizontal plane can each be quickly acquired as compared with a case in which swinging of the hand 12, calculation of the offset amount of the hand 12, shifting of the position of the hand 12, etc. are repeated. In other words, even when the inclination & of the coordinate system C2 of the placement area 200 of the substrate W with respect to the coordinate system C1 of the robot arm 11 in the horizontal plane is acquired, the time required to correct the position PP of substrate W placement in the horizontal plane can be shortened.

According to this embodiment, the hand 12 is operable to hold the substrate W. The hand 12 includes the distal end bifurcated into the first distal end 12a and the second distal end 12b. The detector 14 is a transmission sensor to detect the target member 20 based on whether or not the detection light DL passing through the space S between the first distal end 12a and the second distal end 12b is blocked. The controller 13 is configured or programmed to cause the hand 12 to approach the target member 20 while changing the position of the hand 12 at which the detection light DL is blocked, and acquire the direction of the detection light DL with respect to the hand 12 based on the plurality of positions of the hand 12 at which the detection light DL is blocked. Furthermore, the controller 13 is configured or programmed to calibrate the coordinate system C1 of the robot arm 11 based on the acquired direction of the detection light DL such that the direction in which the hand 12 approaches the target member 20 is perpendicular to the direction of the detection light DL. Accordingly, even when the direction in which the hand 12 approaches the target member 20 is not perpendicular to the direction of the detection light DL, the direction in which the hand 12 approaches the target member 20 can be easily caused to be perpendicular to the direction of the detection light DL. Thus, a decrease in the accuracy of correcting the position PP of substrate W placement in the horizontal plane, which is caused by the direction in which the hand 12 approaches the target member 20 being not perpendicular to the direction of the detection light DL, can be reduced or prevented.

### Advantages of Method for Correcting Position of Substrate Placement by Substrate Transport Robot

According to this embodiment, the first tangent TL1 to the outer periphery 20b of the target member 20 is acquired using the detector 14 while the hand 12 is caused to approach the target member 20 from the first direction in the horizontal plane. Furthermore, the second tangent TL2 to the outer periphery 20b of the target member 20 is acquired using the detector 14 while the hand 12 is caused to approach the target member 20 from the second direction in the horizontal plane different from the first direction. The center position 20a of the target member 20 is acquired based on the acquired first tangent TL1 and the acquired second tangent TL2. Accordingly, similarly to the substrate transport robot system 100, when the first tangent TL1 and the second tangent TL2 are acquired once, the center position 20a of the target member 20 can be acquired immediately based on the first tangent TL1 and the second tangent TL2. Consequently, similarly to the substrate transport robot system 100, the time required to correct the position PP of substrate W placement in the horizontal plane can be shortened.

### Modified Examples

The embodiment disclosed this time must be considered as illustrative in all points and not restrictive. The scope of the present disclosure is not shown by the above description of the embodiment but by the scope of claims for patent, and all modifications (modified examples) within the meaning and scope equivalent to the scope of claims for patent are further included.

For example, while the example in which the controller 13 calibrates the coordinate system C1 of the robot arm 11 based on the acquired direction of the detection light DL such that the direction in which the hand 12 approaches the target member 20 is perpendicular to the direction of the detection light DL has been shown in the aforementioned embodiment, the present disclosure is not limited to this. In the present disclosure, the controller may not calibrate the coordinate system of the robot arm based on the acquired direction of the detection light such that the direction in which the hand approaches the target member is perpendicular to the direction of the detection light. In such a case, the detector is preferably disposed with respect to the hand such that the direction in which the hand approaches the target member is perpendicular to the direction of the detection light.

While the example in which the detector 14 is a transmission sensor to detect the target member 20 based on whether or not the detection light DL passing through the space S between the first distal end 12a and the second distal end 12b is blocked has been shown in the aforementioned embodiment, the present disclosure is not limited to this. In the present disclosure, the detector may be a reflective sensor. Alternatively, the detector may be a sensor that does not use detection light. In such a case, the hand may not be bifurcated.

While the example in which the controller 13 acquires the inclination a of the coordinate system C2 of the placement area 200 of the substrate W with respect to the coordinate system C1 of the robot arm 11 in the horizontal plane based on the center position 20a of the target member 20 in the horizontal plane, the center position 21a of the target member 21 in the horizontal plane, and the previously acquired relative positional relationship in the horizontal plane between the center position 20a of the target member 20 and the center position 21a of the target member 21 has been shown in the aforementioned embodiment, the present disclosure is not limited to this. In the present disclosure, the controller may acquire the inclination of the coordinate system of the placement area of the substrate with respect to the coordinate system of the robot arm in the horizontal plane by a method other than the above method. Alternatively, the controller may not acquire the inclination of the coordinate system of the placement area of the substrate with respect to the coordinate system of the robot arm in the horizontal plane. In such a case, the robot arm and the placement area of the substrate are preferably disposed such that the coordinate system of the placement area of the substrate is not inclined with respect to the coordinate system of the robot arm in the horizontal plane.

While the example in which the substrate transport robot system 100 includes, in addition to the target member 20, the target member 21 disposed at the position different from that position of the target member 20 in the horizontal plane has been shown in the aforementioned embodiment, the present disclosure is not limited to this. In the present disclosure, the substrate transport robot system may include only one target member.

While the example in which the target member 20 is a member for correcting the position PP of substrate W placement in the horizontal plane and in the upward-downward direction has been shown in the aforementioned embodiment, the present disclosure is not limited to this. In the present disclosure, the target member for correcting the position of substrate placement in the horizontal plane may be separate from the target member for correcting the position of substrate placement in the upward-downward direction.

While the example in which the substrate transport robot 10 performs correction of the position PP of substrate W placement in the upward-downward direction in addition to correction of the position PP of substrate W placement in the horizontal plane has been shown in the aforementioned embodiment, the present disclosure is not limited to this. In the present disclosure, the substrate transport robot may perform only correction of the position of substrate placement in the horizontal plane without performing correction of the position of substrate placement in the upward-downward direction.

While the example in which the controller 13, which is provided in the substrate transport robot 10 to control the operation of the robot arm 11 etc., acquires the center position 20a of the target member 20 in the horizontal plane and corrects the position PP of substrate W placement in the horizontal plane has been shown in the aforementioned embodiment, the present disclosure is not limited to this. In the present disclosure, the controller that controls the operation of the robot arm, etc. may be separate from the controller that acquires the center position of the target member in the horizontal plane and corrects the acquired center position of the target member in the horizontal plane and the position of substrate placement in the horizontal plane.

Alternatively, the substrate transport may not include the controller that acquires the center position of the target member in the horizontal plane and corrects the acquired center position of the target member in the horizontal plane and the position of substrate placement in the horizontal plane.

While the example in which the position PP of substrate W placement is corrected has been shown in the aforementioned embodiment, the present disclosure is not limited to this. In the present disclosure, a position of substrate pick-up may be corrected instead of the position of substrate placement, or both the position of substrate placement and the position of substrate pick-up may be corrected. When the position of substrate pick-up is corrected, the target member is a member for performing correction to match the position of substrate pick-up with the placement area of the substrate.

The functionality of the elements disclosed herein may be implemented using circuitry or processing circuitry that includes general purpose processors, special purpose processors, integrated circuits, application specific integrated circuits (ASICs), conventional circuitry and/or combinations thereof that are configured or programmed to perform the disclosed functionality. Processors are considered processing circuitry or circuitry as they include transistors and other circuitry therein. In the present disclosure, the circuitry, units, or means are hardware that carries out the recited functionality or hardware that is programmed to perform the recited functionality. The hardware may be hardware disclosed herein or other known hardware that is programmed or configured to carry out the recited functionality. When the hardware is a processor that may be considered a type of circuitry, the circuitry, means, or units are a combination of hardware and software, and the software is used to configure the hardware and/or processor.

### Aspects

It will be appreciated by those skilled in the art that the exemplary embodiments described above are specific examples of the following aspects.

### Item 1

A substrate transport robot system comprising:
a substrate transport robot to transport a substrate;
a horizontal target member having a circular shape as viewed in an upward-downward direction and used to correct a position of substrate placement and/or a position of substrate pick-up in a horizontal plane; and
a controller; wherein
the substrate transport robot includes:
   a robot arm;
   a hand attached to a distal end of the robot arm; and
   a detector on the hand to detect an outer periphery of the horizontal target member; and
the controller is configured or programmed to:
   acquire a center position of the horizontal target member in the horizontal plane based on a first tangent corresponding to the outer periphery of the horizontal target member acquired using the detector while the hand is caused to approach the horizontal target member from a first direction in the horizontal plane, and a second tangent corresponding to the outer periphery of the horizontal target member acquired using the detector while the hand is caused to approach the horizontal target member from a second direction in the horizontal plane different from the first direction; and
   correct the position of substrate placement and/or the position of substrate pick-up in the horizontal plane based on an acquired center position of the horizontal target member in the horizontal plane and a previously acquired relative positional relationship in the horizontal plane between the center position of the horizontal target member and a placement area of the substrate.

### Item 2

The substrate transport robot system according to item 1, further comprising:
an up-down target member used to correct the position of substrate placement and/or the position of substrate pick-up in the upward-downward direction; wherein
the detector is operable to detect a position of the up-down target member; and
the controller is configured or programmed to:
   acquire the position of the up-down target member in the upward-downward direction based on a timing at which a state in which the detector detects the up-down target member in the upward-downward direction and a state in which the detector does not detect the up-down target member in the upward-downward direction are switched, the timing being acquired by moving the hand in the upward-downward direction with respect to the up-down target member; and
   correct the position of substrate placement and/or the position of substrate pick-up in the upward-downward direction based on an acquired position of the up-down target member in the upward-downward direction and a previously acquired relative positional relationship in the upward-downward direction between the position of the up-down target member and the placement area of the substrate.

### Item 3

The substrate transport robot system according to item 2, wherein the up-down target member is a same target member as the horizontal target member.

### Item 4

The substrate transport robot system according to any one of items 1 to 3, wherein
the horizontal target member includes a first horizontal target member and a second horizontal target member at a position different from a position of the first horizontal target member in the horizontal plane; and
the controller is configured or programmed to acquire an inclination of a coordinate system of the placement area of the substrate with respect to a coordinate system of the robot arm in the horizontal plane based on a center position of the first horizontal target member in the horizontal plane, a center position of the second horizontal target member in the horizontal plane, and a previously acquired relative positional relationship in the horizontal plane between the center position of the first horizontal target member and the center position of the second horizontal target member.

### Item 5

The substrate transport robot system according to any one of items 1 to 4, wherein
the hand includes a distal end bifurcated into a first distal end and a second distal end;
the detector is a transmission sensor to detect the horizontal target member based on whether or not detection light passing through a space between the first distal end and the second distal end is blocked; and
the controller is configured or programmed to:
   cause the hand to approach the horizontal target member while changing a position of the hand at which the detection light is blocked, and acquire a direction of the detection light with respect to the hand based on a plurality of positions of the hand at which the detection light is blocked; and
   calibrate a coordinate system of the robot arm based on an acquired direction of the detection light such that a direction in which the hand approaches the horizontal target member is perpendicular to the direction of the detection light.

### Item 6

A method for correcting a position of substrate placement and/or a position of substrate pick-up by a substrate transport robot, the substrate transport robot including a robot arm, a hand attached to a distal end of the robot arm, and a detector to detect a horizontal target member having a circular shape as viewed in an upward-downward direction, the horizontal target member being used to correct a position of substrate placement and/or a position of substrate pick-up in a horizontal plane, the substrate transport robot being operable to transport a substrate, the method comprising:
acquiring a first tangent corresponding to an outer periphery of the horizontal target member using the detector while the hand is caused to approach the horizontal target member from a first direction in the horizontal plane;
acquiring a second tangent corresponding to the outer periphery of the horizontal target member using the detector while the hand is caused to approach the horizontal target member from a second direction in the horizontal plane different from the first direction;
acquiring a center position of the horizontal target member based on an acquired first tangent and an acquired second tangent; and
correcting the position of substrate placement and/or the position of substrate pick-up in the horizontal plane based on an acquired center position of the horizontal target member and a previously acquired relative positional relationship in the horizontal plane between the center position and a placement area of the substrate.

1. A substrate transport robot system comprising:
a substrate transport robot to transport a substrate;
a horizontal target member having a circular shape as viewed in an upward-downward direction and used to correct a position of substrate placement and/or a position of substrate pick-up in a horizontal plane; and
a controller; wherein
the substrate transport robot includes:
a robot arm;
a hand attached to a distal end of the robot arm; and
a detector on the hand to detect an outer periphery of the horizontal target member; and
the controller is configured or programmed to:
acquire a center position of the horizontal target member in the horizontal plane based on a first tangent corresponding to the outer periphery of the horizontal target member acquired using the detector while the hand is caused to approach the horizontal target member from a first direction in the horizontal plane, and a second tangent corresponding to the outer periphery of the horizontal target member acquired using the detector while the hand is caused to approach the horizontal target member from a second direction in the horizontal plane different from the first direction; and
correct the position of substrate placement and/or the position of substrate pick-up in the horizontal plane based on an acquired center position of the horizontal target member in the horizontal plane and a previously acquired relative positional relationship in the horizontal plane between the center position of the horizontal target member and a placement area of the substrate.

2. The substrate transport robot system according to claim 1, further comprising:
an up-down target member used to correct the position of substrate placement and/or the position of substrate pick-up in the upward-downward direction; wherein the detector is operable to detect a position of the up-down target member; and
the controller is configured or programmed to:
acquire the position of the up-down target member in the upward-downward direction based on a timing at which a state in which the detector detects the up-down target member in the upward-downward direction and a state in which the detector does not detect the up-down target member in the upward-downward direction are switched, the timing being acquired by moving the hand in the upward-downward direction with respect to the up-down target member; and
correct the position of substrate placement and/or the position of substrate pick-up in the upward-downward direction based on an acquired position of the up-down target member in the upward-downward direction and a previously acquired relative positional relationship in the upward-downward direction between the position of the up-down target member and the placement area of the substrate.

3. The substrate transport robot system according to claim 2, wherein the up-down target member is a same target member as the horizontal target member.

4. The substrate transport robot system according to claim 1, wherein
the horizontal target member includes a first horizontal target member and a second horizontal target member at a position different from a position of the first horizontal target member in the horizontal plane; and
the controller is configured or programmed to acquire an inclination of a coordinate system of the placement area of the substrate with respect to a coordinate system of the robot arm in the horizontal plane based on a center position of the first horizontal target member in the horizontal plane, a center position of the second horizontal target member in the horizontal plane, and a previously acquired relative positional relationship in the horizontal plane between the center position of the first horizontal target member and the center position of the second horizontal target member.

5. The substrate transport robot system according to claim 1, wherein
the hand includes a distal end bifurcated into a first distal end and a second distal end;
the detector is a transmission sensor to detect the horizontal target member based on whether or not detection light passing through a space between the first distal end and the second distal end is blocked; and
the controller is configured or programmed to:
cause the hand to approach the horizontal target member while changing a position of the hand at which the detection light is blocked, and acquire a direction of the detection light with respect to the hand based on a plurality of positions of the hand at which the detection light is blocked; and
calibrate a coordinate system of the robot arm based on an acquired direction of the detection light such that a direction in which the hand approaches the horizontal target member is perpendicular to the direction of the detection light.

6. A method for correcting a position of substrate placement and/or a position of substrate pick-up by a substrate transport robot, the substrate transport robot including a robot arm, a hand attached to a distal end of the robot arm, and a detector to detect a horizontal target member having a circular shape as viewed in an upward-downward direction, the horizontal target member being used to correct a position of substrate placement and/or a position of substrate pick-up in a horizontal plane, the substrate transport robot being operable to transport a substrate, the method comprising:
acquiring a first tangent corresponding to an outer periphery of the horizontal target member using the detector while the hand is caused to approach the horizontal target member from a first direction in the horizontal plane;
acquiring a second tangent corresponding to the outer periphery of the horizontal target member using the detector while the hand is caused to approach the horizontal target member from a second direction in the horizontal plane different from the first direction;
acquiring a center position of the horizontal target member based on an acquired first tangent and an acquired second tangent; and
correcting the position of substrate placement and/or the position of substrate pick-up in the horizontal plane based on an acquired center position of the horizontal target member and a previously acquired relative positional relationship in the horizontal plane between the center position and a placement area of the substrate.
